(19) United States
(12) Patent Application Publication
(10) Pub. No.: US 2025/0301888 A1
(43) Pub. Date: Sep. 25, 2025

(54) DISPLAY DEVICE AND MANUFACTURING METHOD THEREOF

(71) Applicant: Japan Display Inc., Tokyo (JP)

(72) Inventors: Hiroshi TABATAKE, Tokyo (JP); Kazuyuki HARADA, Tokyo (JP)

(73) Assignee: Japan Display Inc., Tokyo (JP)

(21) Appl. No.: 19/082,249

(22) Filed: Mar. 18, 2025

(30) Foreign Application Priority Data
Mar. 19, 2024 (JP) 2024-043751

(51) Int. Cl. H10K 59/80; H10K 59/12; H10K 59/122

(52) U.S. Cl. CPC H10K 59/873; H10K 59/1201; H10K 59/122

(57) ABSTRACT

According to one embodiment, a display device includes first and second display elements, a partition, and first and second sealing layers covering the display elements. The first display element includes a first lower electrode, a first upper electrode and a first organic layer. The second display element includes a second lower electrode, a second upper electrode and a second organic layer. The partition is provided between the display elements. The sealing layers have first and second end portions above the partition. The end portions overlap each other in a thickness direction of the first and second sealing layers.

### CROSS-REFERENCE TO RELATED APPLICATION

This application is based upon and claims the benefit of priority from Japanese Patent Application No. 2024-043751, filed Mar. 19, 2024, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. In this type of display devices, a technique which can improve the yield and reliability is required.

### BRIEF DESCRIPTION OF THE DRAWINGS

FIG. 1 is a diagram showing a configuration example of a display device according to an embodiment.

FIG. 2 is a schematic plan view showing an example of the layout of subpixels according to the embodiment.

FIG. 3 is the schematic cross-sectional view of the display device along the III-III line of FIG. 2.

FIG. 4 is a schematic plan view of a partition and a sealing layer according to the embodiment.

FIG. 5 is the schematic cross-sectional view of the display device along the V-V line of FIG. 4.

FIG. 6 is the schematic cross-sectional view of the display device along the VI-VI line of FIG. 4.

FIG. 7 is the schematic cross-sectional view of the display device along the VII-VII line of FIG. 4.

FIG. 8A is a schematic cross-sectional view showing the manufacturing process of the display device according to the embodiment.

FIG. 8B is a schematic cross-sectional view showing a process following FIG. 8A.

FIG. 8C is a schematic cross-sectional view showing a process following FIG. 8B.

FIG. 8D is a schematic cross-sectional view showing a process following FIG. 8C.

FIG. 8E is a schematic cross-sectional view showing a process following FIG. 8D.

FIG. 8F is a schematic cross-sectional view showing a process following FIG. 8E.

FIG. 8G is a schematic cross-sectional view showing a process following FIG. 8F.

FIG. 8H is a schematic cross-sectional view showing a process following FIG. 8G.

FIG. 9A is a schematic cross-sectional view showing the manufacturing method of a display device according to a comparative example.

FIG. 9B is a schematic cross-sectional view showing a process following FIG. 9A.

FIG. 9C is a schematic cross-sectional view showing a process following FIG. 9B.

### DETAILED DESCRIPTION

In general, according to one embodiment, a display device comprises a first display element, a second display element, a partition, a first sealing layer and a second sealing layer. The first display element includes a first lower electrode, a first upper electrode which faces the first lower electrode, and a first organic layer which is located between the first lower electrode and the first upper electrode and emits light based on application of voltage. The second display element includes a second lower electrode, a second upper electrode which faces the second lower electrode, and a second organic layer which is located between the second lower electrode and the second upper electrode and emits light based on application of voltage. The partition is provided between the first display element and the second display element. The first sealing layer covers the first display element. The second sealing layer covers the second display element. The first sealing layer has a first end portion located above the partition. The second sealing layer has a second end portion located above the partition. The first end portion and the second end portion overlap each other in a thickness direction of the first sealing layer and the second sealing layer.

According to another aspect of the embodiment, a manufacturing method of a display device includes forming a first lower electrode and a second lower electrode in a display area, forming a partition located between the first lower electrode and the second lower electrode, forming a first stacked film in the display area, the first stacked film including a first organic layer which emits light based on application of voltage, and a first upper electrode which covers the first organic layer, forming a first insulating layer which covers the first stacked film in the display area, forming, by first etching for the first insulating layer, a first sealing layer which has a first end portion located above the partition and covers a first display element including the first lower electrode, the first organic layer and the first upper electrode, removing a portion of the first stacked film exposed from the first sealing layer by second etching for the first stacked film, forming a second stacked film in the display area after the second etching, the second stacked film including a second organic layer which emits light based on application of voltage, and a second upper electrode which covers the second organic layer, forming a second insulating layer which covers the second stacked film in the display area, forming, by third etching for the second insulating layer, a second sealing layer which has a second end portion overlapping the first end portion in a thickness direction of the first sealing layer and covers a second display element including the second lower electrode, the second organic layer and the second upper electrode, and removing a portion of the second stacked film exposed from the second sealing layer by fourth etching for the second stacked film.

The embodiments can realize the improvement of the yield of a display device or the improvement of reliability.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

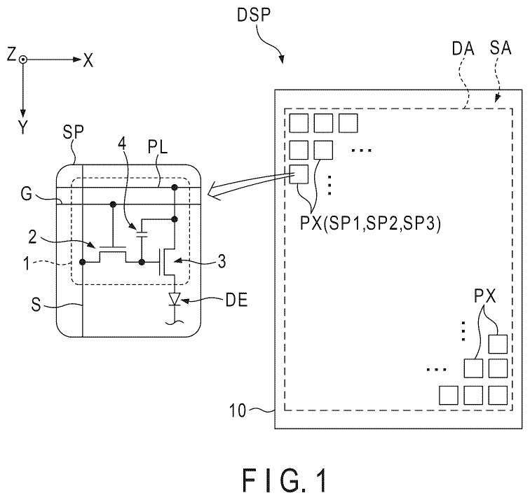

FIG. 1 is a diagram showing a configuration example of a display device DSP according to an embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 and the display area DA are rectangular as seen in plan view. It should be noted that the shape of each of the substrate 10 and the display area DA in plan view is not limited to a rectangle and may be another shape such as a square, a precise circle or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

In the display area DA, a plurality of scanning lines G which supply scanning signals to the pixel circuits 1 of subpixels SP, a plurality of signal lines S which supply video signals to the pixel circuits 1 of subpixels SP and a plurality of power lines PL are provided. In the example of FIG. 1, the scanning line G extends in the X-direction, and the signal line S extends in the Y-direction. However, the configuration is not limited to this example.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

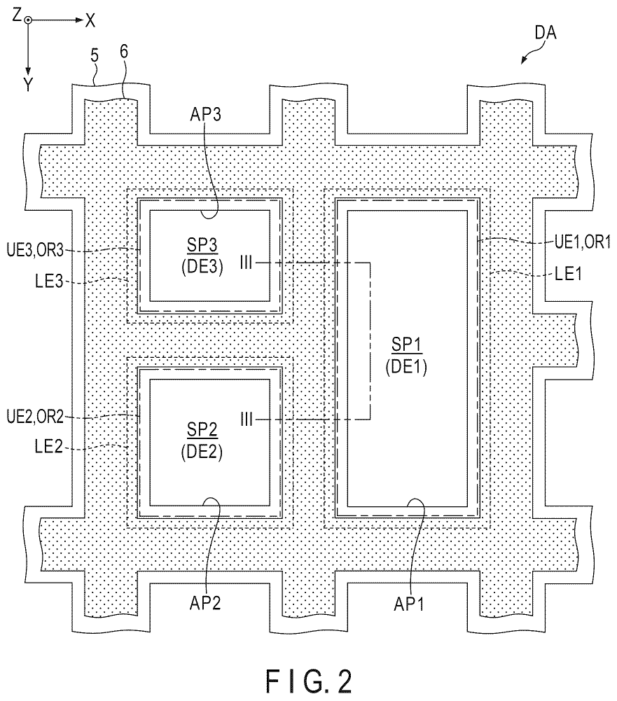

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib layer 5 is provided in the display area DA. The rib layer 5 has pixel apertures AP1, AP2 and AP3 in subpixels SP1, SP2 and SP3, respectively. In the example of FIG. 2, the area of the pixel aperture AP1 is greater than that of the pixel aperture AP2, and the area of the pixel aperture AP2 is greater than that of the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element (first display element) DE1 of subpixel SP1. Of the lower electrode LE2, the upper electrode UE2 and the organic layer OR2, the portions which overlap the pixel aperture AP2 constitute the display element (second display element) DE2 of subpixel SP2. Of the lower electrode LE3, the upper electrode UE3 and the organic layer OR3, the portions which overlap the pixel aperture AP3 constitute the display element (third display element) DE3 of subpixel SP3. Each of the display elements DE1, DE2 and DE3 may further include a cap layer as described later. The rib layer 5 surrounds each of these display elements DE1, DE2 and DE3.

The relationships of the areas of the display elements DE1, DE2 and DE3 are similar to those of the pixel apertures AP1, AP2 and AP3. Specifically, the area of the display element DE1 is the greatest, and the area of the display element DE3 is the least. It should be noted that the relationships of the areas of the display elements DE1, DE2 and DE3 or the relationships of the areas of the pixel apertures AP1, AP2 and AP3 are not limited to this example.

A conductive partition 6 is provided on the rib layer 5. The partition 6 overlaps the rib layer 5 as a whole and has a planar shape similar to that of the rib layer 5. In other words, the partition 6 has an aperture in each of subpixels SP1, SP2 and SP3. From another viewpoint, each of the rib layer 5 and the partition 6 has a grating shape as seen in plan view, and surrounds each of the display elements DE1, DE2 and DE3. The partition 6 functions as lines which apply common voltage to the upper electrodes UE1, UE2 and UE3.

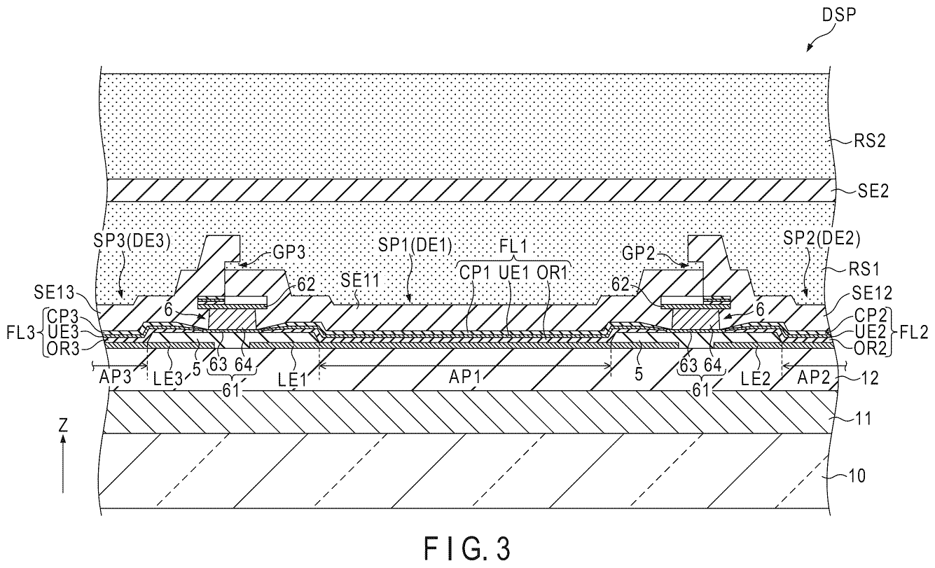

FIG. 3 is the schematic cross-sectional view of the display device DSP along the III-III line of FIG. 2. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

Sealing layers SE11, SE12 and SE13 are provided in subpixels SP1, SP2 and SP3, respectively. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

The sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a touch panel, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer formed of, for example, silver, and a pair of conductive oxide layers covering the upper and lower surfaces of the reflective layer. Each of the conductive oxide layers can be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 consists of a plurality of thin films including a light emitting layer. For example, each of the organic layers OR1, OR2 and OR3 has a structure in which a hole injection layer, a hole transport layer, an electron blocking layer, a light emitting layer, a hole blocking layer, an electron transport layer and an electron injection layer are stacked in order in a Z-direction. It should be noted that each of the organic layers OR1, OR2 and OR3 may have another structure such as a tandem structure including a plurality of light emitting layers.

Each of the cap layers CP1, CP2 and CP3 has, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. It should be noted that at least one of the cap layers CP1, CP2 and CP3 may be omitted.

Each of the bottom layer 63 and stem layer 64 of the partition 6 is formed of a metal material. For the metal material of the bottom layer 63, for example, molybdenum, titanium, titanium nitride (TiN), a molybdenum-tungsten alloy (MoW) or a molybdenum-niobium alloy (MoNb) may be used. For the metal material of the stem layer 64, for example, aluminum, an aluminum-neodymium alloy (AlNd), an aluminum-yttrium alloy (AlY) or an aluminum-silicon alloy (AlSi) may be used. It should be noted that the stem layer 64 may be formed of an insulating material.

For example, the upper portion 62 of the partition 6 has a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy may be used. For the conductive oxide forming the upper layer, for example, ITO or IZO may be used. It should be noted that the upper portion 62 may have a single-layer structure of a metal material. Further, the upper portion 62 may include a layer formed of an insulating material.

Common voltage is applied to the partition 6. This common voltage is applied to each of the upper electrodes UE1, UE2 and UE3 which are in contact with the lower portions 61. Pixel voltage is applied to the lower electrodes LE1, LE2 and LE3 through the pixel circuits 1 provided in subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

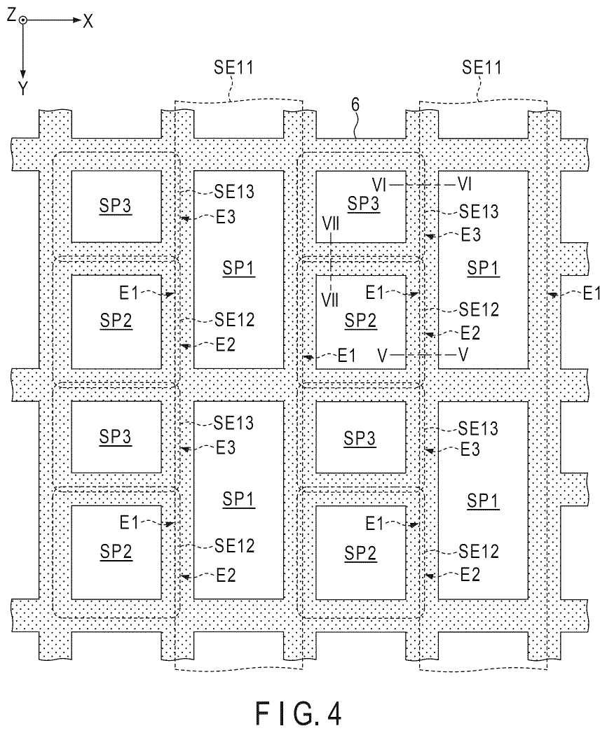

FIG. 4 is a schematic plan view of the partition 6 and the sealing layers SE11, SE12 and SE13. In the example of this figure, each sealing layer SE11 is continuously formed across subpixels SP1 arranged in the Y-direction. Each sealing layer SE12 is formed for a corresponding subpixel SP2. Similarly, each sealing layer SE13 is formed for a corresponding subpixel SP3.

All of the sides forming the outer shapes of the sealing layers SE11, SE12 and SE13 overlap the partition 6. In the following explanation, in each sealing layer SE11, the portion located above the partition 6 along the outer shape of the sealing layer SE11 is referred to as an end portion (first end portion) E1. In each sealing layer SE12, the portion located above the partition 6 along the outer shape of the sealing layer SE12 is referred to as an end portion (second end portion) E2. In each sealing layer SE13, the portion located above the partition 6 along the outer shape of the sealing layer SE13 is referred to as an end portion (third end portion) E3.

In the example of FIG. 4, the end portions E1 and E2 of the adjacent sealing layers SE11 and SE12 overlap each other in the Z-direction. The end portions E1 and E3 of the adjacent sealing layers SE11 and SE13 overlap each other in the Z-direction. Further, the end portions E2 and E3 of the adjacent sealing layers SE12 and SE13 overlap each other in the Z-direction. Here, the Z-direction corresponds to the thickness direction of the sealing layers SE11, SE12 and SE13.

It should be noted that the relationships of the end portions E1, E2 and E3 are not limited to the example of FIG. 4. For example, part of the end portion E1 may not overlap the end portions E2 and E3. Part of the end portion E2 may not overlap the end portions E1 and E3. Further, part of the end portion E3 may not overlap the end portions E1 and E2.

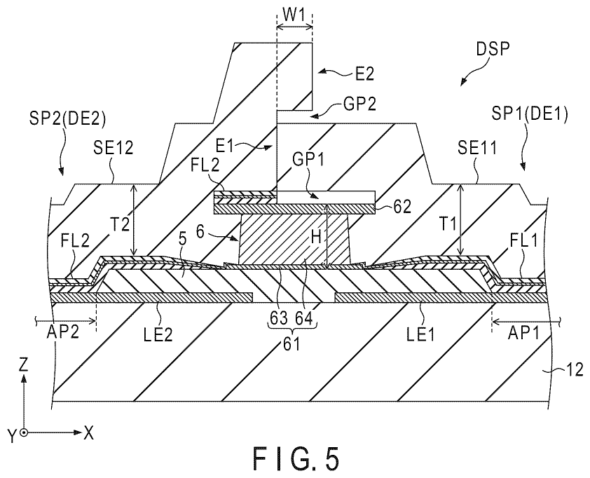

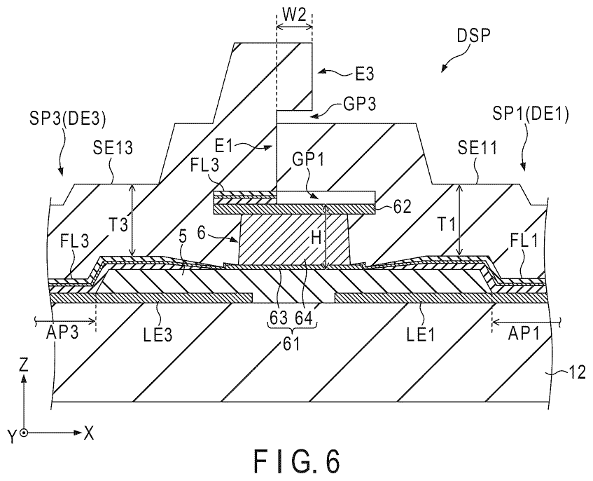

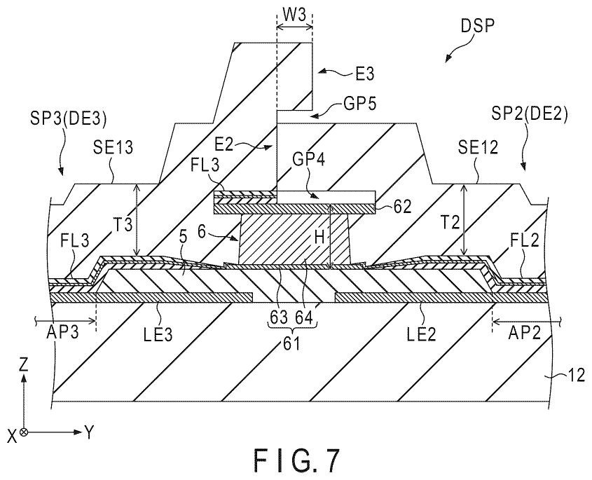

FIG. 5 is the schematic cross-sectional view of the display device DSP along the V-V line of FIG. 4. FIG. 6 is the schematic cross-sectional view of the display device DSP along the VI-VI line of FIG. 4. FIG. 7 is the schematic cross-sectional view of the display device DSP along the VII-VII line of FIG. 4. In these figures, the substrate 10, the circuit layer 11, the resin layer RS1, the sealing layer SE2 and the resin layer RS2 are omitted.

As shown in FIG. 5, the end portion E1 of the sealing layer SE11 located on the partition 6 between subpixels SP1 and SP2 is located between the partition 6 and the end portion E2 of the sealing layer SE12 in the Z-direction. A gap (first gap) GP1 is formed between the upper portion 62 of the partition 6 and the end portion E1 in the Z-direction. The gap GP1 is, for example, a void. It should be noted that the stacked film FL1 may be provided in at least part of an area corresponding to the gap GP1 shown in the figure.

In the example of FIG. 5, the stacked film FL2 is provided between the sealing layer SE12 and the upper portion 62. A gap (second gap) GP2 is formed between the end portion E1 and the end portion E2 in the Z-direction. At least part of the gap GP2 is filled with the resin layer RS1 as shown in, for example, FIG. 3. It should be noted that the stacked film FL2 may be provided in at least part of an area corresponding to the gap GP2 shown in the figure.

In the example of FIG. 5, part of the end portion E1 is in contact with part of the end portion E2 above the partition 6. As another example, the stacked film FL2 may be interposed between the end portions E1 and E2 which are drawn so as to be in contact with each other in the figure.

As shown in FIG. 6, the end portion E1 located on the partition 6 between subpixels SP1 and SP3 is located between the partition 6 and the end portion E3 of the sealing layer SE13 in the Z-direction. In the section of FIG. 6, similarly, the gap GP1 is formed between the upper portion 62 and the end portion E1.

In the example of FIG. 6, the stacked film FL3 is provided between the sealing layer SE13 and the upper portion 62. A gap (third gap) GP3 is formed between the end portion E1 and the end portion E3 in the Z-direction. At least part of the gap GP3 is filled with the resin layer RS1 as shown in, for example, FIG. 3. It should be noted that the stacked film FL3 may be provided in at least part of an area corresponding to the gap GP3 shown in the figure.

In the example of FIG. 6, part of the end portion E1 is in contact with part of the end portion E3 above the partition 6. As another example, the stacked film FL3 may be interposed between the end portions E1 and E3 which are drawn so as to be in contact with each other in the figure.

As shown in FIG. 7, the end portion E2 located on the partition 6 between subpixels SP2 and SP3 is located between the partition 6 and the end portion E3 in the Z-direction. A gap (fourth gap) GP4 is formed between the upper portion 62 and the end portion E2 in the Z-direction. The gap GP4 is, for example, a void. It should be noted that the stacked film FL2 may be provided in at least part of an area corresponding to the gap GP4 shown in the figure.

In the example of FIG. 7, similarly, the stacked film FL3 is provided between the sealing layer SE13 and the upper portion 62. A gap (fifth gap) GP5 is formed between the end portion E2 and the end portion E3 in the Z-direction. At least part of the gap GP5 is filled with the resin layer RS1 in a manner similar to that of the gaps GP2 and GP3 shown in FIG. 3. It should be noted that the stacked film FL3 may be provided in at least part of an area corresponding to the gap GP5 shown in the figure.

In the example of FIG. 7, part of the end portion E2 is in contact with part of the end portion E3 above the partition 6. As another example, the stacked film FL3 may be interposed between the end portions E2 and E3 which are drawn so as to be in contact with each other in the figure.

As shown in FIG. 5 to FIG. 7, the sealing layer SE11 has thickness T1. The sealing layer SE12 has thickness T2. The sealing layer SE13 has thickness T3. The partition 6 has height H. Height H corresponds to the distance from the upper surface of the rib layer 5 to the upper surface of the upper portion 62.

For example, thicknesses T1, T2 and T3 are equal to each other (T1=T2=T3). Thicknesses T1, T2 and T3 are greater than or equal to height H (T1, T2, T3>H). When the sealing layers SE11, SE12 and SE13 are thick in this manner, the display elements DE1, DE2 and DE3 and the partition 6 located around the display elements can be satisfactorily covered with the sealing layers SE11, SE12 and SE13.

It should be noted that the relationships of thicknesses T1, T2 and T3 and height H are not limited to the example shown here. For example, at least two of thicknesses T1, T2 and T3 may differ from each other. Further, at least one of thicknesses T1, T2 and T3 may be less than height H.

Width W1 which is the width of the overlap between the end portions E1 and E2 as shown in in FIG. 5, width W2 which is the width of the overlap between the end portions E1 and E3 as shown in in FIG. 6 and width W3 which is the width of the overlap between the end portions E2 and E3 as shown in FIG. 7 are, for example, greater than or equal to 1 μm, more specifically, greater than or equal to 2 μm. All of these widths W1, W2 and W3 are less than the width of the partition 6 (the width of the upper portion 62). Widths W1, W2 and W3 may be equal to each other or different from each other.

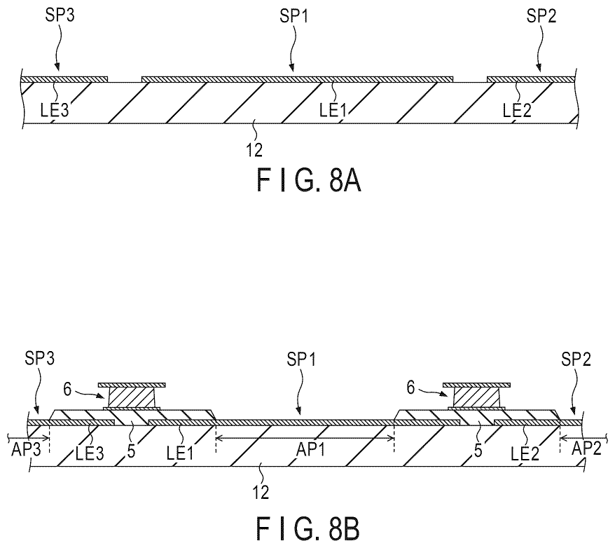

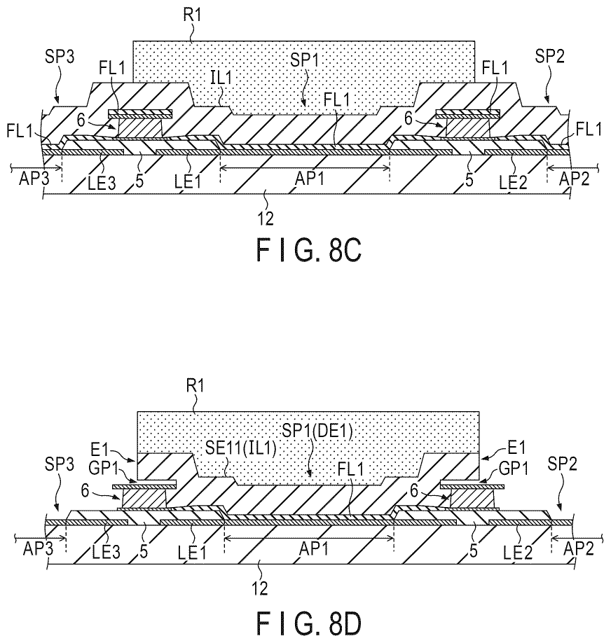

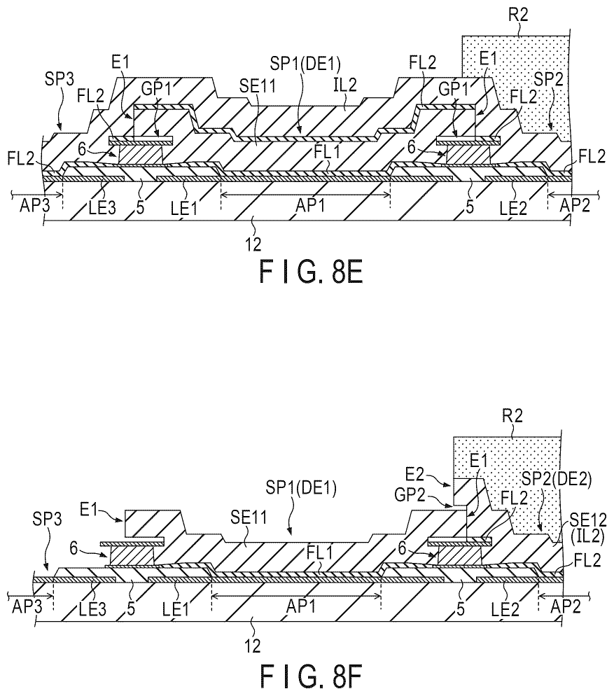

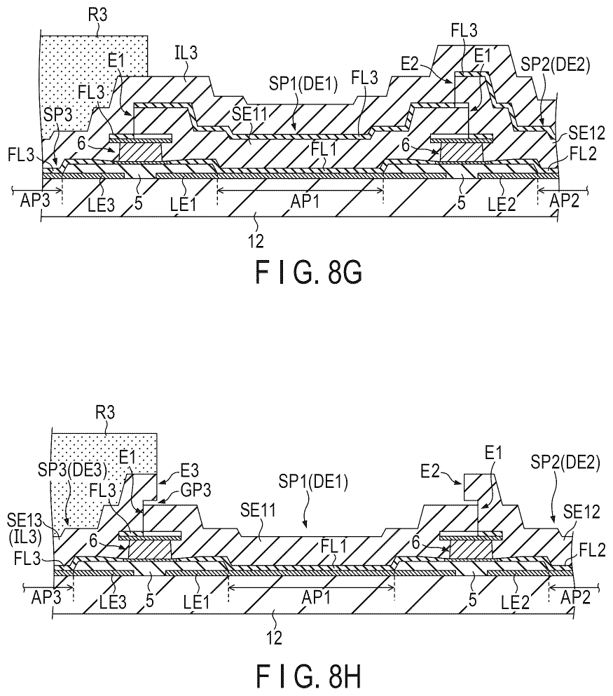

Now, this specification explains an example of the manufacturing method of the display device DSP. Each of FIG. 8A to FIG. 8H is a schematic cross-sectional view showing the manufacturing process of the display device DSP. In FIG. 8A to FIG. 8H, subpixels SP1, SP2 and SP3 are mainly looked at, and the elements located on the lower side of the organic insulating layer 12 are omitted.

To form the display device DSP, first, the circuit layer 11 and the organic insulating layer 12 are formed on the substrate 10. Subsequently, as shown in FIG. 8A, the lower electrodes LE1, LE2 and LE3 are formed on the organic insulating layer 12.

Subsequently, the rib layer 5 and the partition 6 are formed as shown in FIG. 8B. The pixel apertures AP1, AP2 and AP3 of the rib layer 5 may be provided after the formation of the partition 6 or may be provided before the formation of the partition 6.

After the formation of the rib layer 5 and the partition 6, a process for forming the display elements DE1, DE2 and DE3 is performed. In the embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

To form the display element DE1, first, as shown in FIG. 8C, the stacked film FL1 and an insulating layer (first insulating layer) IL1 which covers the stacked film FL1 are formed. The stacked film FL1 includes, as shown in FIG. 3, the organic layer OR1 which is in contact with the lower electrode LE1 through the pixel aperture AP1, the upper electrode UE1 which covers the organic layer OR1 and the cap layer CP1 which covers the upper electrode UE1. The insulating layer IL1 is the layer to be processed into the sealing layer SE11 and is formed of an inorganic insulating material. To form the organic layer OR1, the upper electrode UE1 and the cap layer CP1, vapor deposition may be used. To form the insulating layer IL1, chemical vapor deposition (CVD) may be used.

For example, the stacked film FL1 and the insulating layer IL are formed in the entire part of the display area DA and the surrounding area SA. The stacked film FL1 is divided into a plurality of portions by the partition 6 having an overhang shape. The insulating layer IL1 continuously covers the portions into which the stacked film FL1 is divided, and the partition 6.

Subsequently, the stacked film FL1 and the insulating layer IL1 are patterned. In this patterning, as shown in FIG. 8C, a resist R1 is provided on the insulating layer IL1. The resist R1 covers subpixel SP1 and part of the partition 6 around the subpixel.

Subsequently, first etching for the insulating layer IL1 and second etching for the stacked film FL1 are performed in order. In the first etching, the portion of the insulating layer IL1 exposed from the resist R1 is removed. By this process, as shown in FIG. 8D, the sealing layer SE11 having the end portion E1 located above the partition 6 is formed. The first etching is, for example, dry etching.

In the second etching, the portion of the stacked film FL1 exposed from the sealing layer SE11 is removed. For example, the second etching includes wet etching and dry etching processes which are performed in order for the cap layer CP1, the upper electrode UE1 and the organic layer OR1.

In the second etching, the stacked film FL1 located on the partition 6 could be also removed. By this process, the gap GP1 described above is formed between the end portion E1 and the partition 6. Since the stacked film FL1 which is in contact with the lower electrode LE1 through the pixel aperture AP1 is completely covered with the sealing layer SE11, this stacked film FL1 is not eroded by the second etching. The stacked film FL1 and lower electrode LE1 left in subpixel SP1 in this manner constitute the display element DE1.

The resist R1 is removed after the first etching and the second etching. Further, as shown in FIG. 8E, the stacked film FL2 and an insulating layer (second insulating layer) IL2 which covers the stacked film FL2 are formed. The stacked film FL2 includes, as shown in FIG. 3, the organic layer OR2 which is in contact with the lower electrode LE2 through the pixel aperture AP2, the upper electrode UE2 which covers the organic layer OR2 and the cap layer CP2 which covers the upper electrode UE2. The insulating layer IL2 is the layer to be processed into the sealing layer SE12 and is formed of an inorganic insulating material. To form the organic layer OR2, the upper electrode UE2 and the cap layer CP2, vapor deposition may be used. To form the insulating layer IL2, CVD may be used.

For example, the stacked film FL2 and the insulating layer IL2 are formed in the entire part of the display area DA and the surrounding area SA. The stacked film FL2 is divided into a plurality of portions by the partition 6 having an overhang shape. The stacked film FL2 could be divided in the end portion E1 as well. However, the configuration is not limited to this example. The insulating layer IL2 continuously covers the portions into which the stacked film FL2 is divided, and the partition 6. For example, at least part of the gap GP1 remains as a void after the formation of the stacked film FL2 and the insulating layer IL2.

Subsequently, the stacked film FL2 and the insulating layer IL2 are patterned. In this patterning, as shown in FIG. 8E, a resist R2 is provided on the insulating layer IL2. The resist R2 covers subpixel SP2 and part of the partition 6 around the subpixel. The resist R2 is partly located above the end portion E1.

Subsequently, third etching for the insulating layer IL2 and fourth etching for the stacked film FL2 are performed in order. In the third etching, the portion of the insulating layer IL2 exposed from the resist R2 is removed. By this process, as shown in FIG. 8F, the sealing layer SE12 having the end portion E2 located above the partition 6 is formed. The third etching is, for example, dry etching.

In the fourth etching, the portion of the stacked film FL2 exposed from the sealing layer SE12 is removed. For example, the fourth etching includes wet etching and dry etching processes which are performed in order for the cap layer CP2, the upper electrode UE2 and the organic layer OR2.

In the fourth etching, the stacked film FL2 located on the end portion E1 could be also removed. By this process, the gap GP2 described above is formed between the end portion E1 and the end portion E2. Although not shown in the section of FIG. 8F, the gap GP4 shown in FIG. 7 is also formed by the fourth etching.

Since the stacked film FL2 which is in contact with the lower electrode LE2 through the pixel aperture AP2 is completely covered with the sealing layer SE12, this stacked film FL2 is not eroded by the fourth etching. The stacked film FL2 and lower electrode LE2 left in subpixel SP2 in this manner constitute the display element DE2. The resist R2 is removed after the third etching and the fourth etching.

The resist R2 is removed after the third etching and the fourth etching. Further, as shown in FIG. 8G, the stacked film FL3 and an insulating layer (third insulating layer) IL3 which covers the stacked film FL3 are formed. The stacked film FL3 includes, as shown in FIG. 3, the organic layer OR3 which is in contact with the lower electrode LE3 through the pixel aperture AP3, the upper electrode UE3 which covers the organic layer OR3 and the cap layer CP3 which covers the upper electrode UE3. The insulating layer IL3 is the layer to be processed into the sealing layer SE13 and is formed of an inorganic insulating material. To form the organic layer OR3, the upper electrode UE3 and the cap layer CP3, vapor deposition may be used. To form the insulating layer IL3, CVD may be used.

For example, the stacked film FL3 and the insulating layer IL3 are formed in the entire part of the display area DA and the surrounding area SA. The stacked film FL3 is divided into a plurality of portions by the partition 6 having an overhang shape. The stacked film FL3 could be divided in the end portions E1 and E2 as well. However, the configuration is not limited to this example. The insulating layer IL3 continuously covers the portions into which the stacked film FL3 is divided, and the partition 6.

Subsequently, the stacked film FL3 and the insulating layer IL3 are patterned. In this patterning, as shown in FIG. 8G, a resist R3 is provided on the insulating layer IL3. The resist R3 covers subpixel SP3 and part of the partition 6 around the subpixel. The resist R3 is partly located above the end portion E1. Although not shown in the section of FIG. 8G, the resist R3 is partly located above the end portion E2 in the boundary between subpixels SP2 and SP3.

Subsequently, fifth etching for the insulating layer IL3 and sixth etching for the stacked film FL3 are performed in order. In the fifth etching, the portion of the insulating layer IL3 exposed from the resist R3 is removed. By this process, as shown in FIG. 8H, the sealing layer SE13 having the end portion E3 located above the partition 6 is formed. The fifth etching is, for example, dry etching.

In the sixth etching, the portion of the stacked film FL3 exposed from the sealing layer SE13 is removed. For example, the sixth etching includes wet etching and dry etching processes which are performed in order for the cap layer CP3, the upper electrode UE3 and the organic layer OR3.

In the sixth etching, the stacked film FL3 located under the end portion E3 could be also removed. By this process, the gap GP3 described above is formed between the end portion E1 and the end portion E3. Although not shown in the section of FIG. 8H, the gap GP5 shown in FIG. 7 is also formed by the fourth etching.

Since the stacked film FL3 which is in contact with the lower electrode LE3 through the pixel aperture AP3 is completely covered with the sealing layer SE13, this stacked film FL3 is not eroded by the sixth etching. The stacked film FL3 and lower electrode LE3 left in subpixel SP3 in this manner constitute the display element DE3. The resist R3 is removed after the fifth etching and the sixth etching.

After the display elements DE1, DE2 and DE3 are formed, the resin layer RS1, sealing layer SE2 and resin layer RS2 shown in FIG. 3 are formed in order. As described above, at least part of the gaps GP2, GP3 and GP5 may be filled with the resin layer RS1.

The embodiment described above can realize the improvement of the yield of the display device DSP and the improvement of reliability. The effects obtained from this improvement are explained below.

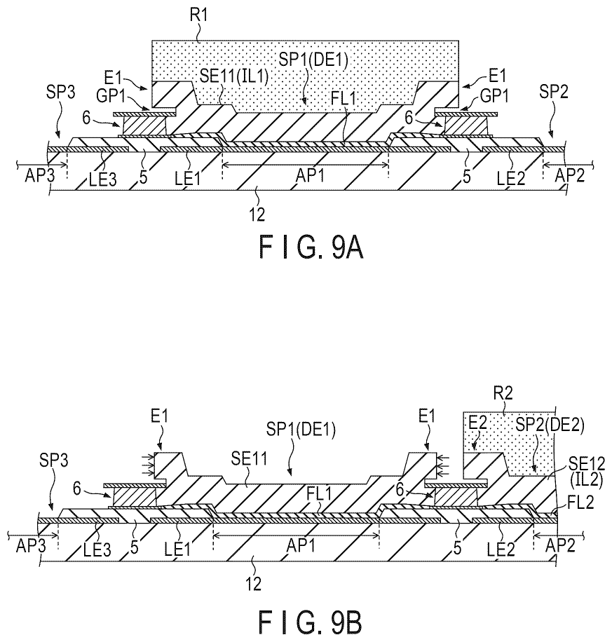

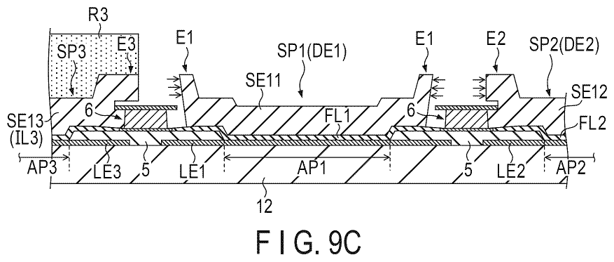

Each of FIG. 9A to FIG. 9C is a schematic cross-sectional view showing the manufacturing method of a display device according to a comparative example of the embodiment. The flow of the manufacturing of the display device DSP is similar to that shown in FIG. 8A to FIG. 8H. FIG. 9A shows the state immediately after the implementation of the first etching and the second etching. FIG. 9B shows the state immediately after the implementation of the third etching and the fourth etching. FIG. 9C shows the state immediately after the implementation of the fifth etching and the sixth etching.

The section of FIG. 9A is almost the same as the section of FIG. 8D. However, in FIG. 9A, the widths of the resist R1 and the sealing layer SE11 are less than those of FIG. 8D. Thus, the width of the end portion E1 located on the partition 6 is also less than that of FIG. 8D.

In this comparative example, when the display element DE2 and the sealing layer SE12 are formed, the resist R2 is provided so as not to overlap the end portion E1. In this case, the insulating layer IL2 which covers the end portion E1 is completely removed in the third etching. Therefore, there is a possibility that the end portion E1 is eroded in the third etching. If the end portion E1 is eroded, as shown in FIG. 9B, the end portion E1 is retracted toward the pixel aperture AP1.

Further, in this comparative example, when the display element DE3 and the sealing layer SE13 are formed, the resist R3 is provided so as not to overlap the end portion E1 or E2. In this case, the insulating layer IL3 which covers the end portions E1 and E2 is completely removed in the fifth etching. Therefore, there is a possibility that the end portions E1 and E2 are eroded in the fifth etching. If the end portion E1 is eroded, as shown in FIG. 9C, the end portion E1 is further retracted toward the pixel aperture AP1. If the end portion E2 is eroded, the end portion E2 is retracted toward the pixel aperture AP2.

In FIG. 9C, the end portion E1 is spaced apart from the partition 6, and the stacked film FL1 constituting the display element DE1 is exposed from the sealing layer SE11. If this sealing defect occurs, moisture may enter the stacked film FL1, and the stacked film FL1 may be corroded. As a result, the display defect of the display element DE1 may occur. When the sealing layer SE12 is severely eroded in the fifth etching, a similar problem may occur in the display element DE2.

However, in the present embodiment, a part the end portion E1 of the sealing layer SE11 overlaps the end portion E2 of the sealing layer SE12. In this case, this part of the end portion E1 is protected by the sealing layer SE12 (insulating layer IL2) in the third etching and the fifth etching.

In addition, in the embodiment, another part of the end portion E1 of the sealing layer SE11 overlaps the end portion E3 of the sealing layer SE13. In this case, this part of the end portion E1 is protected by the sealing layer SE13 (insulating layer IL3) in the fifth etching.

Further, in the embodiment, a part of the end portion E2 of the sealing layer SE12 overlaps the end portion E3 of the sealing layer SE13. In this case, this part of the end portion E2 is protected by the sealing layer SE13 (insulating layer IL3) in the fifth etching.

Because of these factors, in the embodiment, the retraction of the end portions E1 and E2 shown in the comparative example is prevented. As a result, the yield of the display device DSP can be improved, and further, the reliability of the display device DSP can be improved.

All of the display devices and manufacturing methods that can be implemented by a person of ordinary skill in the art through arbitrary design changes to the display device and manufacturing method described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a first display element including:
a first lower electrode;
a first upper electrode which faces the first lower electrode; and
a first organic layer which is located between the first lower electrode and the first upper electrode and emits light based on application of voltage;
a second display element including:
a second lower electrode;
a second upper electrode which faces the second lower electrode; and
a second organic layer which is located between the second lower electrode and the second upper electrode and emits light based on application of voltage;
a partition between the first display element and the second display element;
a first sealing layer which covers the first display element; and
a second sealing layer which covers the second display element, wherein
the first sealing layer has a first end portion above the partition,
the second sealing layer has a second end portion above the partition, and
the first end portion and the second end portion overlap each other in a thickness direction of the first sealing layer and the second sealing layer.

2. The display device of claim 1, wherein
the first end portion is located between the partition and the second end portion in the thickness direction, and
a first gap is formed between the partition and the first end portion in the thickness direction.

3. The display device of claim 2, wherein
the first gap is a void.

4. The display device of claim 2, wherein
a second gap is formed between the first end portion and the second end portion in the thickness direction.

5. The display device of claim 4, further comprising a resin layer which covers the first sealing layer and the second sealing layer, wherein
at least part of the second gap is filled with the resin layer.

6. The display device of claim 1, wherein
the first sealing layer and the second sealing layer are in contact with each other above the partition.

7. The display device of claim 1, wherein
an area of the first display element is greater than an area of the second display element.

8. The display device of claim 1, wherein
the partition includes a conductive lower portion and an upper portion which has an end portion protruding from a side surface of the lower portion.

9. The display device of claim 1, wherein
each of the first sealing layer and second sealing layer is formed of an inorganic insulating material.

10. The display device of claim 1, wherein
both a thickness of the first sealing layer and a thickness of the second sealing layer are greater than a height of the partition.

11. A manufacturing method of a display device, the method including:
forming a first lower electrode and a second lower electrode in a display area;
forming a partition located between the first lower electrode and the second lower electrode;
forming a first stacked film in the display area, the first stacked film including:
a first organic layer which emits light based on application of voltage; and
a first upper electrode which covers the first organic layer;
forming a first insulating layer which covers the first stacked film in the display area;
forming, by first etching for the first insulating layer, a first sealing layer which has a first end portion located above the partition and covers a first display element including the first lower electrode, the first organic layer and the first upper electrode;
removing a portion of the first stacked film exposed from the first sealing layer by second etching for the first stacked film;
forming a second stacked film in the display area after the second etching, the second stacked film including:
a second organic layer which emits light based on application of voltage; and
a second upper electrode which covers the second organic layer;
forming a second insulating layer which covers the second stacked film in the display area;
forming, by third etching for the second insulating layer, a second sealing layer which has a second end portion overlapping the first end portion in a thickness direction of the first sealing layer and covers a second display element including the second lower electrode, the second organic layer and the second upper electrode; and
removing a portion of the second stacked film exposed from the second sealing layer by fourth etching for the second stacked film.

12. The manufacturing method of claim 11, wherein
a portion of the first stacked film located on the partition is removed in the second etching, thereby forming a first gap between the partition and the first end portion in the thickness direction.

13. The manufacturing method of claim 12, wherein
the first gap remains as a void after the second sealing layer is formed.

14. The manufacturing method of claim 12, wherein
a portion of the second stacked film located on the first end portion is removed in the fourth etching, thereby forming a second gap between the first end portion and the second end portion in the thickness direction.

15. The manufacturing method of claim 14, further including
forming a resin layer which covers the first sealing layer and the second sealing layer, wherein
at least part of the second gap is filled with the resin layer.

16. The manufacturing method of claim 11, wherein
the first sealing layer and the second sealing layer are in contact with each other above the partition.

17. The manufacturing method of claim 11, wherein
an area of the first display element is greater than an area of the second display element.

18. The manufacturing method of claim 11, wherein
the partition includes a conductive lower portion and an upper portion which has an end portion protruding from a side surface of the lower portion.

19. The manufacturing method of claim 11, wherein
each of the first sealing layer and the second sealing layer is formed of an inorganic insulating material.

20. The manufacturing method of claim 11, wherein
both a thickness of the first sealing layer and a thickness of the second sealing layer are greater than a height of the partition.
